(19) United States
(12) Patent Application Publication
(10) Pub. No.: US 2013/0092820 A1
(43) Pub. Date: Apr. 18, 2013

(54) SOLID-STATE IMAGING DEVICE AND IMAGING DEVICE

(71) Applicant: OLYMPUS CORPORATION, Tokyo (JP)

(72) Inventor: Yoshiaki Takemoto, Tokyo (JP)

(73) Assignee: OLYMPUS CORPORATION, Tokyo (JP)

(21) Appl. No.: 13/653,880

(22) Filed: Oct. 17, 2012

(30) Foreign Application Priority Data
Oct. 18, 2011 (JP) 2011-228678

(51) Int. Cl. H01L 27/146

(52) U.S. Cl. 250/208.1

(57) ABSTRACT

A solid-state imaging device includes a first substrate to an n^{th} substrate being electrically connected to each other via connection portions and being stacked. An m^{th} substrate includes a pixel region which has pixels including a photoelectric conversion element. A substrate other than the m^{th} substrate includes a first vertical scanning circuit and a second vertical scanning circuit including a circuit element provided to drive the pixels. In a region of the other substrate, at least parts of the first vertical scanning circuit and the second vertical scanning circuit are disposed within an overlapping region overlapping the pixel region in a vertical direction. n is an integer greater than or equal to 2 and m is an integer greater than or equal to 1 and less than or equal to n.

### BACKGROUND OF THE INVENTION

1. Field of the Invention

The present invention relates to a solid-state imaging device and an imaging device.

Priority is claimed on Japanese Patent Application No. 2011-228678, filed Oct. 18, 2011, the content of which is incorporated herein by reference.

2. Description of Related Art

In recent years, video cameras, electronic still cameras, and the like have generally come into wide use. Charge-coupled device (CCD)-type or amplification-type solid-state imaging devices have been used in such cameras. In the amplification-type solid-state imaging devices, signal charges generated and stored by photoelectric conversion elements of pixels on which light is incident are guided toward amplification units installed in the pixels, and the signals amplified by the amplification units are output from the pixels. In the amplification-type solid-state imaging devices, such pixels are arrayed in a two-dimensional matrix form. Examples of the amplification-type solid-state imaging device include a complementary metal oxide semiconductor (CMOS)-type solid-state imaging device that uses a CMOS transistor.

In the past, a general CMOS-type solid-state imaging device has utilized a method of sequentially reading signal charges generated by photoelectric conversion elements of pixels arrayed in a two-dimensional matrix form from each row. According to this method, an exposure timing in the photoelectric conversion element of each pixel is determined by start and end of the reading of the signal charge. Therefore, the exposure timing is different in each row. Therefore, when a fast-moving subject is imaged using such a CMOS-type solid-state imaging device, the subject in the captured image may be distorted. The distortion of the subject may be reduced by driving the pixels at a high speed.

In order to get rid of the distortion of the subject, a simultaneous imaging function (global shutter function) of realizing simultaneity of the storage of the signal charges has been proposed. CMOS-type solid-state imaging devices having the global shutter function tend to be used for many uses. In the CMOS-type solid-state imaging devices having the global shutter function, the signal charges generated by the photoelectric conversion elements are generally stored until reading is performed. Therefore, a storage capacitor having a light-shielding property is necessary.

In the CMOS-type solid-state imaging devices according to the related art, after simultaneous exposure of all of the pixels, the signal charges generated by the photoelectric conversion elements are simultaneously transmitted to the storage capacitors in all of the pixels and are stored once, and then the signal charges are sequentially converted into pixel signals to be read at a predetermined reading timing.

Japanese Unexamined Patent Application, First Publication No. 2006-49361 discloses a solid-state imaging device in which a MOS image sensor chip in which a micro-pad is formed on the side of a wiring layer in each unit cell and a signal-processing chip in which a micro-pad is formed on the side of the wiring layer at a position corresponding to the micro-pad of the MOS image sensor chip are connected by a micro-bump. Further, Japanese Unexamined Patent Application, First Publication No. 2010-225927 discloses a solid-state imaging device in which high-speed driving is realized while simultaneity is ensured by driving a MOS image sensor chip from a control circuit installed in a signal-processing chip to reduce pixel irregularity.

### SUMMARY OF THE INVENTION

According to a first aspect of the present invention, a solid-state imaging device is provided. First to n^{th} (where n is an integer greater than or equal to 2) substrates are electrically connected to each other via connection portions and are stacked. An m^{th} (where m is an integer greater than or equal to 1 and less than or equal to n) substrate includes a pixel region which has pixels including a photoelectric conversion element. A substrate other than the m^{th} substrate includes a driving circuit including a circuit element provided to drive the pixel. In a region of the other substrate, at least a part of the driving circuit is disposed within an overlapping region overlapping the pixel region in a vertical direction.

The driving circuit may be a vertical scanning circuit.

The vertical scanning circuit may include unit circuits arrayed in the vertical direction by a number necessary to drive all of the pixels. The vertical scanning circuit may be divided into a plurality of vertical circuit blocks.

The divided vertical circuit blocks may be shifted and disposed at least in one of a horizontal direction and the vertical direction.

The divided vertical circuit blocks may be shifted and disposed so as not to overlap each other.

The divided vertical circuit blocks may be disposed so as to have a positional relationship in which parts of the vertical circuit blocks overlap each other, when viewed in the horizontal direction.

The plurality of vertical circuit blocks may be disposed to be included in the overlapping region.

A substrate through-electrode penetrating through the substrate may be formed in a location other than the locations at which the vertical circuit blocks are disposed in the overlapping region.

In at least one substrate of the first to n^{th} substrates, the substrate through-electrode penetrating through the substrate may be formed.

The first to n^{th} substrates may be stacked in order and an electrode portion exchanging a signal with the outside is formed in a rear surface of the n^{th} substrate.

The substrate through-electrode may be connected to the electrode portion formed in the rear surface of the n^{th} substrate.

A glass substrate may be adhered and joined to a surface of the first substrate on which light is incident.

The driving circuit may be formed in the second substrate. A reading circuit may be formed from the third to n^{th} substrates.

The driving circuit included in another substrate may include a signal storage unit that stores a signal generated by the photoelectric conversion element included in the m^{th} substrate and input via the connection portion.

The other substrate may include a reading circuit that includes a circuit element provided to read a signal output by the pixel. The reading circuit may read the signal stored by the signal storage unit.

In a region of the other substrate, at least a part of the reading circuit may be disposed in the overlapping region overlapping the pixel region in the vertical direction.

According to a second aspect of the present invention, a solid-state imaging device is provided. First to n^{th} (where n is an integer greater than or equal to 2) substrates are electrically connected to each other via connection portions and are stacked. An m^{th} (where m is an integer greater than or equal to 1 and less than or equal to n) substrate includes a pixel region which has pixels including a photoelectric conversion element. A substrate other than the m^{th} substrate includes a reading circuit including a circuit element provided to read a signal output by the pixel. In a region of the other substrate, at least a part of the reading circuit is disposed within an overlapping region overlapping the pixel region in a vertical direction.

The reading circuit may be a horizontal scanning circuit.

The horizontal scanning circuit may include unit circuits arrayed in a horizontal direction by a number necessary to read the signals output by all of the pixels. The horizontal scanning circuit may be divided into a plurality of horizontal circuit blocks.

The divided horizontal circuit blocks may be shifted and disposed at least in one of the horizontal and vertical directions.

The divided horizontal circuit blocks may be shifted and disposed so as not to overlap each other.

The divided horizontal circuit blocks may be disposed so as to have a positional relationship in which parts of the horizontal circuit blocks overlap each other, when viewed in the vertical direction.

The plurality of horizontal circuit blocks may be disposed to be included in the overlapping region.

A substrate through-electrode penetrating through the substrate may be formed in a location other than the locations at which the horizontal circuit blocks are disposed in the overlapping region.

In at least one substrate of the first to n^{th} substrates, the substrate through-electrode penetrating through the substrate may be formed.

The first to n^{th} substrates may be stacked in order and an electrode portion exchanging a signal with the outside is formed in a rear surface of the n^{th} substrate.

The substrate through-electrode may be connected to the electrode portion formed in the rear surface of the n^{th} substrate.

A glass substrate may be adhered and joined to a surface of the first substrate on which light is incident.

The reading circuit may be formed in the second substrate. A driving circuit may be formed from the third to n^{th} substrates.

The reading circuit included in another substrate may read the signal from a signal storage unit that stores a signal generated by the photoelectric conversion element included in the m^{th} substrate.

The other substrate may include a driving circuit that includes a circuit element provided to drive the pixel. The driving circuit may include the signal storage unit.

In a region of the other substrate, at least a part of the driving circuit may be disposed in the overlapping region overlapping the pixel region in the vertical direction.

According to a third aspect of the present invention, an imaging device is provided. First to n^{th} (where n is an integer greater than or equal to 2) substrates are electrically connected to each other via connection portions and are stacked. An m^{th} (where m is an integer greater than or equal to 1 and less than or equal to n) substrate includes a pixel region which has pixels including a photoelectric conversion element. A substrate other than the m^{th} substrate includes a driving circuit including a circuit element provided to drive the pixel. In a region of the other substrate, at least a part of the driving circuit is disposed within an overlapping region overlapping the pixel region in a vertical direction.

According to a fourth aspect of the present invention, an imaging device is provided. First to n^{th} (where n is an integer greater than or equal to 2) substrates are electrically connected to each other via connection portions and are stacked. An m^{th} (where m is an integer greater than or equal to 1 and less than or equal to n) substrate includes a pixel region which has pixels including a photoelectric conversion element. A substrate other than the m^{th} substrate includes a reading circuit including a circuit element provided to read a signal output by the pixel. In a region of the other substrate, at least a part of the reading circuit is disposed within an overlapping region overlapping the pixel region in a vertical direction.

### BRIEF DESCRIPTION OF THE DRAWINGS

FIG. 1 is a block diagram illustrating the configuration of an imaging device according to a first embodiment of the present invention.

FIG. 2 is a block diagram illustrating the configuration of a solid-state imaging device of the imaging device according to the first embodiment of the present invention.

FIG. 3 is a circuit diagram illustrating the circuit configuration of a pixel according to the first embodiment of the present invention.

FIG. 4 is a sectional view illustrating the solid-state imaging device according to the first embodiment of the present invention.

FIG. 5A is a plan view illustrating a first substrate of the solid-state imaging device according to the first embodiment of the present invention.

FIG. 5B is a plan view illustrating a second substrate of the solid-state imaging device according to the first embodiment of the present invention.

FIG. 6A is a sectional view illustrating the solid-state imaging device according to a second embodiment of the present invention.

FIG. 6B is a plan view illustrating the solid-state imaging device according to the second embodiment of the present invention.

FIG. 7A is a sectional view illustrating the solid-state imaging device according to the second embodiment of the present invention.

FIG. 7B is a plan view illustrating the solid-state imaging device according to the second embodiment of the present invention.

FIG. 8 is a block diagram illustrating the configuration of a solid-state imaging device of an imaging device according to a third embodiment of the present invention.

FIG. 9 is a circuit diagram illustrating the circuit configuration of a pixel according to the third embodiment of the present invention.

FIG. 10 is a circuit diagram illustrating the circuit configuration of a pixel according to the third embodiment of the present invention.

FIG. 11 is a timing chart illustrating a process of a pixel according to the third embodiment of the present invention.

FIG. 12 is a timing chart illustrating a process of a pixel according to the third embodiment of the present invention.

FIG. 13 is a sectional view illustrating the solid-state imaging device according to the third embodiment of the present invention.

### DETAILED DESCRIPTION OF THE INVENTION

### First Embodiment

Hereinafter, a first embodiment of the present invention will be described with reference to the drawings. The following detailed description includes specific detailed contents as an example. Of course, those skilled in the art should understand that the detailed contents may be varied or modified and the variations and modifications of the contents are within the scope of the present invention. Accordingly, various embodiments to be described below have generality of the present invention described in the claims and do not limit the present invention described in the claims.

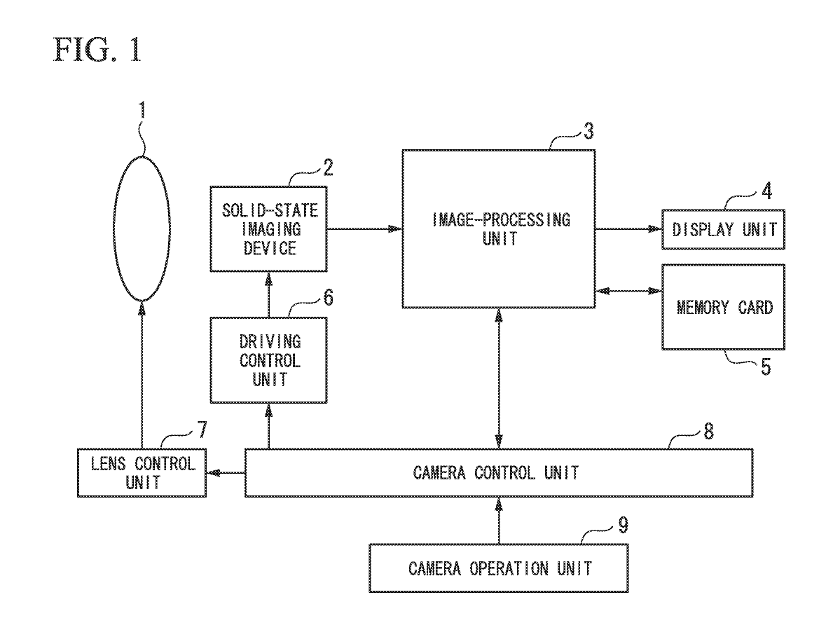

FIG. 1 is a diagram illustrating the configuration of an imaging device according to this embodiment. The imaging device according to this embodiment may be an electronic apparatus having an imaging function and may be a digital video camera, an endoscope, and the like in addition to a digital camera.

The imaging device shown in FIG. 1 includes a lens 1, a solid-state imaging device 2, an image-processing unit 3, a display unit 4, a driving control unit 6, a lens control unit 7, a camera control unit 8, and a camera operation unit 9. Although a memory card 5 is shown in FIG. 1, the memory card 5 may be configured to be detachably mounted on the imaging device. Thus, the memory card 5 may not be a unique constituent element of the imaging device.

Each block shown in FIG. 1 can be realized by various hardware components such as a CPU of a computer, an electric circuit component such as a memory, an optical component such as a lens, an operation component such as a button or a switch. Each block shown in FIG. 1 can also be realized by software such as a computer program. Here, each block is illustrated as a functional block realized in association with the hardware and software. Accordingly, of course, those skilled in the art should understand that the functional blocks are realized in various forms by the combination of the hardware and software.

The lens 1 is a photographing lens that forms an optical image of a subject on an imaging surface of the solid-state imaging device 2. The solid-state imaging device 2 includes a plurality of pixel cells. The solid-state imaging device 2 converts the optical image of the subject formed by the lens 1 into a digital image signal through photoelectric conversion and outputs the digital image signal. The image-processing unit 3 performs various kinds of digital image processing on the image signal output from the solid-state imaging device 2.

The display unit 4 displays an image based on the image signal for display digitally processed by the image-processing unit 3. The display unit 4 is configured to reproduce and display a still image and display a moving image (live-view) in which images of an imaging range are displayed in real time. The driving control unit 6 controls the process of the solid-state imaging device 2 in response to an instruction from the camera control unit 8. The driving control unit 6 may be installed within the solid-state imaging device 2. The lens control unit 7 controls a stop or a focal position of the lens 1 in response to an instruction from the camera control unit 8.

The camera control unit 8 controls the entire imaging device. The process of the camera control unit 8 is defined in a program stored in a ROM included in the imaging device. The camera control unit 8 reads the program and performs various kinds of control in accordance with the contents defined by the program. The camera operation unit 9 includes various operation members used for a user to input various operations to the imaging device and outputs a signal based on the result of the operation input to the camera control unit 8. Specific examples of the camera operation unit 9 include a power switch used to turn the imaging device on and off, a release button used to give an instruction to photograph a still image, and a still image photographing mode switch used to switch a still image photographing mode between a single shot mode and a continuous shot mode. The memory card 5 is a recording medium that stores image signals processed for recording by the image-processing unit 3.

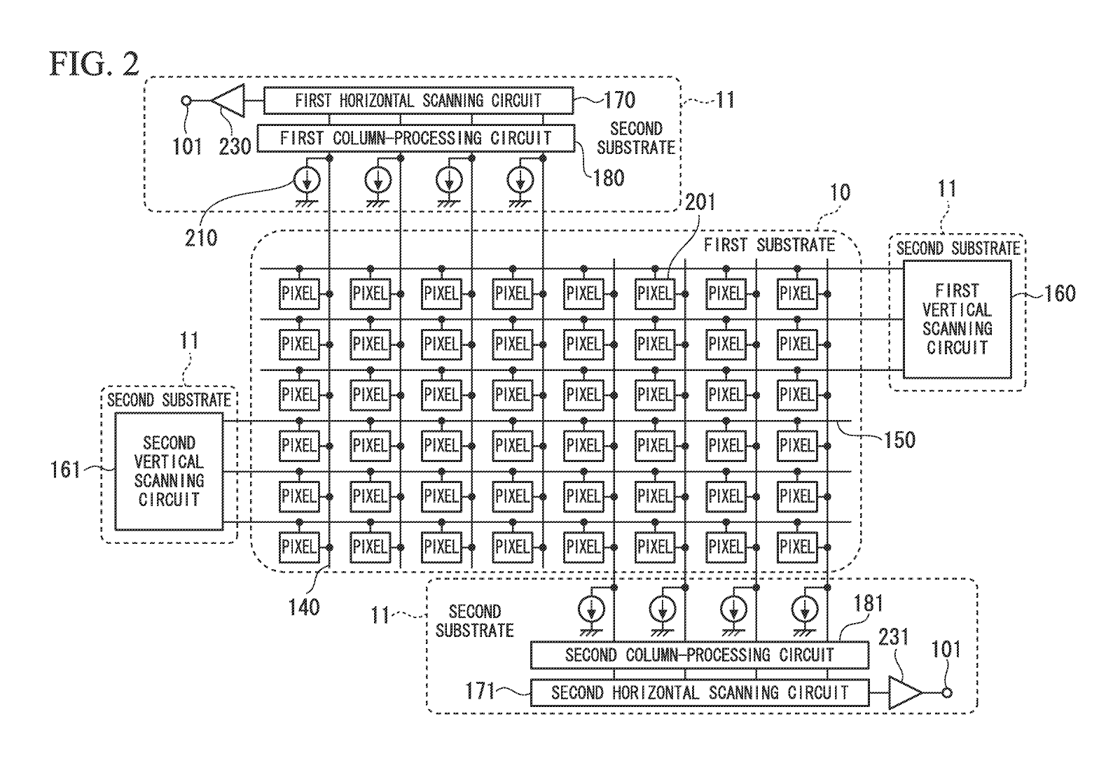

FIG. 2 is a block diagram illustrating the configuration of the solid-state imaging device 2. In the illustrated example, the solid-state imaging device 2 includes a plurality of pixels 201, a first vertical scanning circuit 160, a second vertical scanning circuit 161, a first horizontal scanning circuit 170, a second horizontal scanning circuit 171, a first column-processing circuit 180, a second column-processing circuit 181, a vertical signal line current source 210, and output amplifiers 230 and 231.

The solid-state imaging device 2 according to this embodiment includes two substrates, a first substrate 10 and a second substrate 11. The first substrate 10 and the second substrate 11 are stacked, and thus connection portions electrically connect the first substrate 10 to the second substrate 11. The pixels 201 are arrayed in the first substrate 10. The first vertical scanning circuit 160, the second vertical scanning circuit 161, the first horizontal scanning circuit 170, the second horizontal scanning circuit 171, the first column-processing circuit 180, the second column-processing circuit 181, the vertical signal line current source 210, and the output amplifiers 230 and 231 are disposed in the second substrate 11. The disposition positions of the illustrated circuit constituent elements do not necessarily accord with the actual disposition positions of the circuit constituent elements.

The pixel 201 includes a photoelectric conversion element and a memory. A pixel signal output by the pixel 201 is a unit partition signal for extracting a digital signal when the solid-state imaging device 2 captures an image. In the illustrated example, forty-eight pixels 201 are arrayed in six rows and eight columns, but the array of the pixels 201 is merely an example. The number of rows and the number of columns may be one or more. In the illustrated example, the matrix form of the pixels 201 is schematically illustrated, and the pixels 201 are not disposed separately.

In this embodiment, a region of all the pixels 201 included in the solid-state imaging device 2 is configured as a reading target region of a pixel signal, but part of the region of all the pixels 201 included in the solid-state imaging device 2 may be configured as the reading target region. The reading target region preferably includes at least all of the pixels 201 of an effective pixel region. The reading target region may include optical black pixels (pixels from which light is normally shielded) disposed outside the effective pixel region. A pixel signal read from the optical black pixel is, for example, used to correct a dark current component.

The first vertical scanning circuit 160 is connected to the pixels 201 of the first row to the third row via row control lines 150. The second vertical scanning circuit 161 is connected to the pixels 201 of the fourth row to the sixth row via the row control lines 150. The first vertical scanning circuit 160 and the second vertical scanning circuit 161 include, for example, a shift register, perform driving control on the pixels 201, and output the pixel signals which are signals output by the pixels 201 to vertical signal lines 140. The driving control includes a resetting process, a storing process, and a signal reading process for the pixels 201. To perform the driving control, the first vertical scanning circuit 160 and the second vertical scanning circuit 161 output control signals (control pulses) to the pixels 201 via the row control lines 150 installed in the pixels 201 and independently control the pixels 201 for each row.

In the illustrated example, the first vertical scanning circuit 160 is connected to the pixels 201 of the first row to the third row via the row control lines 150. The second vertical scanning circuit 161 is connected to the pixels 201 of the fourth to sixth rows via the row control lines 150. However, the configuration of the present embodiment is not limited thereto. For example, the first vertical scanning circuit 160 may be configured to be connected to the pixels 201 of the first row to an m^{th} row (where m is an integer of 1 to 5) via the row control lines 150. The second vertical scanning circuit 161 may be configured to be connected to the pixels 201 of an (m+1)^{th} row to the sixth row via the row control lines 150.

The first column-processing circuit 180 is connected to the pixels 201 of the first column to the fourth column via the vertical signal lines 140. The second column-processing circuit 181 is connected to the pixels 201 of the fifth column to the eighth column via the vertical signal lines 140. The first column-processing circuit 180 and the second column-processing circuit 181 perform signal processing such as noise-removing or amplification on the pixel signals output from the pixels 201 and input via the vertical signal lines 140.

In the illustrated example, the first column-processing circuit 180 is connected to the pixels 201 of the first to fourth columns via the vertical signal lines 140. The second column-processing circuit 181 is connected to the pixels 201 of the fifth column to the eighth column via the vertical signal lines 140. However, the configuration of the present embodiment is not limited thereto. For example, the first column-processing circuit 180 may be connected to the pixels 201 of the first column to an n^{th} column (where n is an integer of 1 to 7) via the vertical signal lines 140. The second column-processing circuit 181 may be connected to the pixels 201 of an (n+1)^{th} column to the eighth column via the vertical signal lines 140.

The first horizontal scanning circuit 170 includes, for example, a shift register. The first horizontal scanning circuit 170 reads the pixel signals by selecting a column of the pixels 201 from which the pixel signals are read, sequentially selecting the first column-processing circuit 180 relevant to the selected column of the pixels 201, and sequentially outputting the pixel signals from the first column-processing circuit 180 to the output amplifier 230. The second horizontal scanning circuit 171 includes, for example, a shift register. The second horizontal scanning circuit 171 reads the pixel signals by selecting a column of the pixels 201 from which the pixel signals are read, sequentially selecting the second column-processing circuit 181 relevant to the selected column of the pixels 201, and sequentially outputting the pixel signals from the second column-processing circuit 181 to the output amplifier 231.

The vertical signal line current source 210 supplies a current to the vertical signal lines 140. The output amplifier 230 performs signal processing on the pixel signals input from the first horizontal scanning circuit 170 and outputs the processed pixel signals to the outside via a pad 101. The output amplifier 231 performs signal processing on the pixel signals input from the second horizontal scanning circuit 171 and outputs the processed pixel signals to the outside via the pad 101. In the illustrated example, one row control line 150 connected from the first vertical scanning circuit 160 and the second vertical scanning circuit 161 to the pixels 201 is illustrated, but the plurality of row control lines 150 are actually used.

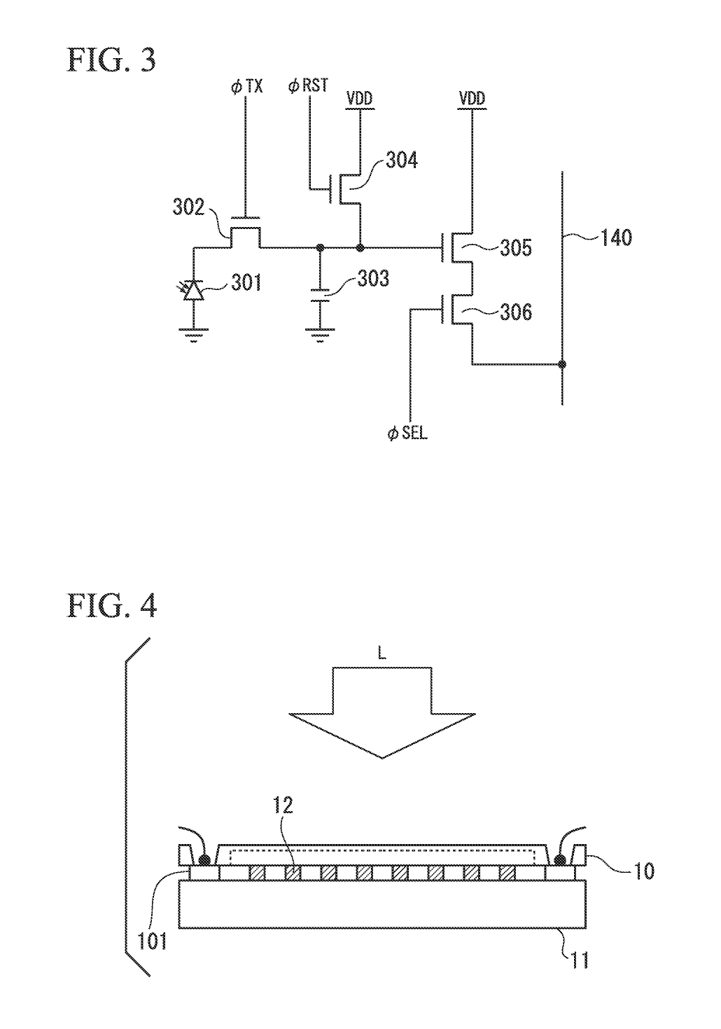

FIG. 3 is a diagram illustrating the circuit configuration of the pixel 201. The pixel 201 includes a photoelectric conversion element 301, a transmission transistor 302, a floating diffusion (FD) 303, an FD reset transistor 304, an amplification transistor 305, and a select transistor 306. The disposition positions of the circuit constituent elements illustrated in FIG. 3 do not necessarily accord with the actual disposition positions of the circuit constituent elements.

One end of the photoelectric conversion element 301 is grounded. A drain terminal of the transmission transistor 302 is connected to the other end of the photoelectric conversion element 301. A gate terminal of the transmission transistor 302 is connected to the first vertical scanning circuit 160 or the second vertical scanning circuit 161, and thus a transmission pulse φTX is supplied. One end of the FD 303 is connected to a source terminal of the transmission transistor 302 and the other end of the FD 303 is grounded. A drain terminal of the FD reset transistor 304 is connected to a supply voltage VDD and a source terminal of the FD reset transistor 304 is connected to the source terminal of the transmission transistor 302. A gate terminal of the FD reset transistor 304 is connected to the first vertical scanning circuit 160 or the second vertical scanning circuit 161, and thus an FD reset pulse φRST is supplied.

A drain terminal of the amplification transistor 305 is connected to the supply voltage VDD. A gate terminal, which is an input portion of the amplification transistor 305, is connected to the source terminal of the transmission transistor 302. A drain terminal of the select transistor 306 is connected to a source terminal of the amplification transistor 305, and a source terminal of the select transistor 306 is connected to the vertical signal line 140. A gate terminal of the select transistor 306 is connected to the first vertical scanning circuit 160 or the second vertical scanning circuit 161, and thus a select pulse φSEL is supplied. The source and drain terminals may be reversed by reversing the polarity of each of the above-described transistors.

The photoelectric conversion element 301 is, for example, a photodiode. The photoelectric conversion element 301 generates (creates) a signal charge based on incident light, and retains and stores the generated (created) signal charge. The transmission transistor 302 is a transistor that transmits the signal charge stored in the photoelectric conversion element 301 to the FD 303. The On/Off of the transmission transistor 302 is controlled by the transmission pulse φTX from the first vertical scanning circuit 160 or the second vertical scanning circuit 161. The FD 303 is a capacitor that temporarily retains and stores the signal charge transmitted from the photoelectric conversion element 301.

The FD reset transistor 304 is a transistor that resets the FD 303.

The On/Off of the FD reset transistor 304 is controlled by the FD reset pulse φRST from the first vertical scanning circuit 160 or the second vertical scanning circuit 161. The photoelectric conversion element 301 can be reset by simultaneously turning on the FD reset transistor 304 and the transmission transistor 302. Resets of the FD 303 or the photoelectric conversion element 301 is to control the amount of charge stored in the FD 303 or the photoelectric conversion element 301 and set the state (potential) of the FD 303 or the photoelectric conversion element 301 to a reference state (a reference potential or a reset level).

The amplification transistor 305 is a transistor that outputs an amplified signal obtained by amplifying a signal, which is input to its gate terminal and is based on the signal charge stored in the FD 303, from its source terminal.

The select transistor 306 is a transistor that selects the pixel 201 and delivers the output of the amplification transistor 305 to the vertical signal line 140. The On/Off of the select transistor 306 is controlled by the select pulse φSEL from the first vertical scanning circuit 160 or the second vertical scanning circuit 161.

Next, the process of the solid-state imaging device 2 will be described. The signal charge generated and stored through the photoelectric conversion by the photoelectric conversion element 301 is read to the FD 303 by applying the transmission pulse φTX to the gate electrode of the transmission transistor 302. By the signal charge is read to the FD 303, the potential of the FD 303 is changed. A signal voltage corresponding to the change in the potential is applied to the gate electrode of the amplification transistor 305. Then, the signal voltage amplified by the amplification transistor 305 is output as a pixel signal to the vertical signal line 140.

As shown in FIG. 2, the pixel signal output to the vertical signal line 140 is input to the output amplifier 230 via the first column-processing circuit 180 and the first horizontal scanning circuit 170. Alternatively, the pixel signal output to the vertical signal line 140 is input to the output amplifier 231 via the second column-processing circuit 181 and the second horizontal scanning circuit 171. The output amplifiers 230 and 231 amplify the input pixel signal and output the amplified pixel signal. The first vertical scanning circuit 160 and the second vertical scanning circuit 161 are synchronized with each other by a signal line (not shown), and thus a timing of a control signal is controlled such that the row select pulse φSEL does not simultaneously enter a Hi state in a plurality of rows of the first to n^{th} columns of the pixels 201 included in a pixel array 130.

FIG. 4 is a sectional view illustrating the solid-state imaging device 2. In the illustrated example, the solid-state imaging device 2 includes a first substrate 10, a second substrate 11, connection portions 12, and pads 101. The first substrate 10 and the second substrate 11 are stacked. Of two main surfaces (a surface with a relatively larger surface area than a side surface) of the first substrate 10, light L is emitted to the main surface opposed to the second substrate 11. The connection portions 12 are formed between the first substrate 10 and the second substrate 11. Therefore, the first substrate 10 and the second substrate 11 are electrically connected to each other by the connection portions 12. The connection portion 12 is a joining portion between the substrates using, for example, a micro bump or a joining portion connected between the substrates in accordance with a direct joining method. The pads 101 are formed between the first substrate 10 and the second substrate 11 and in the circumferences of the first substrate 10 and the second substrate 11. When each circuit formed in the first substrate 10 and the second substrate 11 is electrically connected to the outside and inputs and outputs signals, the signals are input and output via the pads 101.

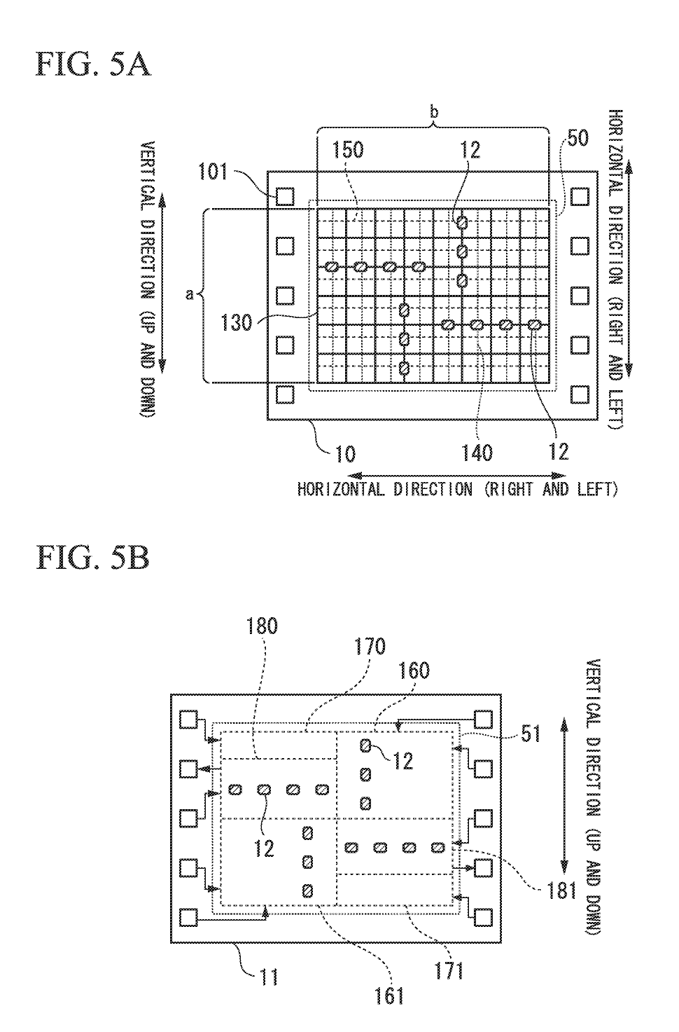

FIG. 5A is a plan view illustrating the planar configuration of the first substrate 10 of the solid-state imaging device 2. FIG. 5B is a plan view illustrating the planar configuration of the second substrate 11 of the solid-state imaging device 2. Here, the long side direction of the first substrate 10 and the second substrate 11, which is illustrate in the drawing, is referred to as a horizontal direction and the short side direction thereof is referred to as a vertical direction. To facilitate the description of the positions of regions in the first substrate 10 and the second substrate 11, sides in the horizontal direction are referred to as right and left sides and sides in the vertical direction are referred to as upper and lower sides.

In the illustrated example, of the two main surfaces of the first substrate 10, the pixel array 130 is disposed on the main surface to which light is emitted. The pixel array 130 is a pixel group in which the plurality of pixels 201 are arranged in a two-dimensional shape and a (where a is an integer) pixels 201 are arranged in the vertical direction and b (where b is an integer) pixels 201 are arranged in the horizontal direction. A region in which the pixels 201 (the pixel array 130) are disposed is referred to as a pixel region 50. The pixel 201 mentioned here is a unit partition from which a digital signal is extracted when an image is acquired. In this embodiment, a circuit group including one photoelectric conversion element corresponds to the pixel 201. The pixel array 130 includes the vertical signal lines 140 and the row control lines 150.

The vertical signal lines 140 are connected to the first column-processing circuit 180 and the second column-processing circuit 181 formed in the second substrate 11 via the connection portions 12. The row control lines 150 are connected to the first vertical scanning circuit 160 and the second vertical scanning circuit 161 formed in the second substrate 11 via the connection portions 12.

The first vertical scanning circuit 160 formed in the second substrate 11 is connected to the pixels 201 of the first row to an x^{th} row (where x is an integer) of the pixel array 130 formed in the first substrate 10 via the row control lines 150 and the connection portions 12. Further, the second vertical scanning circuit 161 formed in the second substrate 11 is connected to the pixels 201 of an (x+1)^{th} row to an a^{th} row (where a is an integer greater than x) of the pixel array 130 formed in the first substrate 10 via the row control lines 150 and the connection portions 12. In the illustrated example, the first vertical scanning circuit 160 is formed in the right upper region of the region within the second substrate 11. The second vertical scanning circuit 161 is formed in the left lower region of the region within the second substrate 11.

The first column-processing circuit 180 formed in the second substrate 11 is connected to the pixels of the first column to a y^{th} column (where y is an integer) of the pixel array 130 formed in the first substrate 10 via the vertical signal lines 140 and the connection portions 12. The second column-processing circuit 181 formed in the second substrate 11 is connected to the pixels of a (y+1)^{th} column to a b^{th} column (where b is an integer greater than y) of the pixel array 130 formed in the first substrate 10 via the vertical signal lines 140 and the connection portions 12. In the illustrated example, the first column-processing circuit 180 is formed in a region on the left side of the first vertical scanning circuit 160 and the upper side of the second vertical scanning circuit 161 in the region of the second substrate 11. The second column-processing circuit 181 is formed in a region on the lower side of the first vertical scanning circuit 160 and on the right side of the second vertical scanning circuit 161.

The first horizontal scanning circuit 170 formed in the second substrate 11 is connected to the first column-processing circuit 180. In the illustrated example, the first horizontal scanning circuit 170 is formed in a region on the upper side of the first column-processing circuit 180 in the region of the second substrate 11. Further, the second horizontal scanning circuit 171 formed in the second substrate 11 is connected to the second column-processing circuit 181. In the illustrated example, the second horizontal scanning circuit 171 is formed in a region on the lower side of the second column-processing circuit 181 in the region of the second substrate 11.

In the region of the second substrate 11, the first vertical scanning circuit 160, the second vertical scanning circuit 161, the first horizontal scanning circuit 170, the second horizontal scanning circuit 171, the first column-processing circuit 180, and the second column-processing circuit 181 are formed in an overlapping region 51 which is a region overlapping in the vertical direction with the pixel region 50 in which the pixels 201 are formed in the first substrate 10. Although not illustrated, in the region of the second substrate 11, the vertical signal line current source 210 and the output amplifiers 230 and 231 are formed in the overlapping region 51 overlapping in the vertical direction with the pixel region 50 in which the pixels 201 are formed in the first substrate 10.

The first vertical scanning circuit 160, the second vertical scanning circuit 161, the first horizontal scanning circuit 170, the second horizontal scanning circuit 171, the first column-processing circuit 180, and the second column-processing circuit 181 exchange signals with the outside via the pads 101. The first vertical scanning circuit 160, the second vertical scanning circuit 161, the first horizontal scanning circuit 170, and the second horizontal scanning circuit 171 mentioned here refer to general circuits that generate signals to drive the pixels in accordance with signals input from the outside and input appropriate driving signals to the pixels or a column-processing circuit, and do not refer to specific circuits. Further, the first column-processing circuit 180 and the second column-processing circuit 181 refer to general circuits that appropriately process signals output from the pixels and have a function of removing noise or amplifying a signal, and do not refer to specific circuits.

In the illustrated example, the connection portions 12 connected to the first vertical scanning circuit 160 and the second horizontal scanning circuit 171 are connected to the pixel array 130 of the same columns, respectively, but the present embodiment is not limited thereto. These connection portions 12 may be connected to the pixel array 130 of different columns. Further, the connection portions 12 connected to the first column-processing circuit 180 and the second column-processing circuit 181 are connected to the pixel array 130 of the same row, but the present embodiment is not limited thereto. These connection portions 12 may be connected to the pixel array 130 of different rows.

In this embodiment, as described above, the first substrate 10 and the second substrate 11 are stacked. The first substrate 10 and the second substrate 11 are electrically connected to each other by the connection portions 12. The pixels 201 are formed in the first substrate 10. In the region of the second substrate 11, the first vertical scanning circuit 160, the second vertical scanning circuit 161, the first horizontal scanning circuit 170, the second horizontal scanning circuit 171, the first column-processing circuit 180, the second column-processing circuit 181, the vertical signal line current source 210, and the output amplifiers 230 and 231 are formed in the overlapping region 51 overlapping in the vertical direction with the pixel region 50 in which the pixels 201 are formed in the first substrate 10.

According to such a configuration, it is possible to increase the occupation area ratio of the pixels 201 to the chip area (the surface area of a chip or a chip size) of the solid-state imaging device 2 without reduction in the circuit sizes of the first vertical scanning circuit 160, the second vertical scanning circuit 161, the first horizontal scanning circuit 170, the second horizontal scanning circuit 171, the first column-processing circuit 180, the second column-processing circuit 181, the vertical signal line current source 210, and the output amplifiers 230 and 231, that is, without deterioration in function.

In this embodiment, a vertical scanning circuit is divided into the first vertical scanning circuit 160 and the second vertical scanning circuit 161, a column-processing circuit is divided into the first column-processing circuit 180 and the second column-processing circuit 181, and a horizontal scanning circuit is divided into the first horizontal scanning circuit 170 and the second horizontal scanning circuit 171. According to such a configuration, in the region of the second substrate 11, the first vertical scanning circuit 160, the second vertical scanning circuit 161, the first horizontal scanning circuit 170, the second horizontal scanning circuit 171, the first column-processing circuit 180, the second column-processing circuit 181, the vertical signal line current source 210, and the output amplifiers 230 and 231 can all be formed in the overlapping region 51 overlapping in the vertical direction with the pixel region 50 in which the pixels 201 are formed in the first substrate 10. Further, since regularity of a layout such as drawing of a wire becomes better, shading caused due to irregularity of circuit characteristics can be prevented from occurring.

### Second Embodiment

Next, a second embodiment of the present invention will be described with reference to the drawings. A difference between the configurations of a solid-state imaging device of this embodiment and the solid-state imaging device 2 of the first embodiment is as follows. That is, in this embodiment, a through-electrode region is formed on the front surface (the main surface on the side of the first substrate 10) of the main surfaces of the second substrate 11. Rear-surface electrodes and protruding electrodes are formed on the rear surface (the main surface opposite the first substrate 10) of the main surfaces of the second substrate 11. A substrate through-electrode is formed to electrically connect the rear-surface electrode to the front surface of the main surfaces of the second substrate 11. Of the two main surfaces of the first substrate 10, a micro-lens and a glass substrate are provided on the main surface (the main surface opposite the second substrate) to which light is emitted. The other configuration and process are the same as those of the first embodiment.

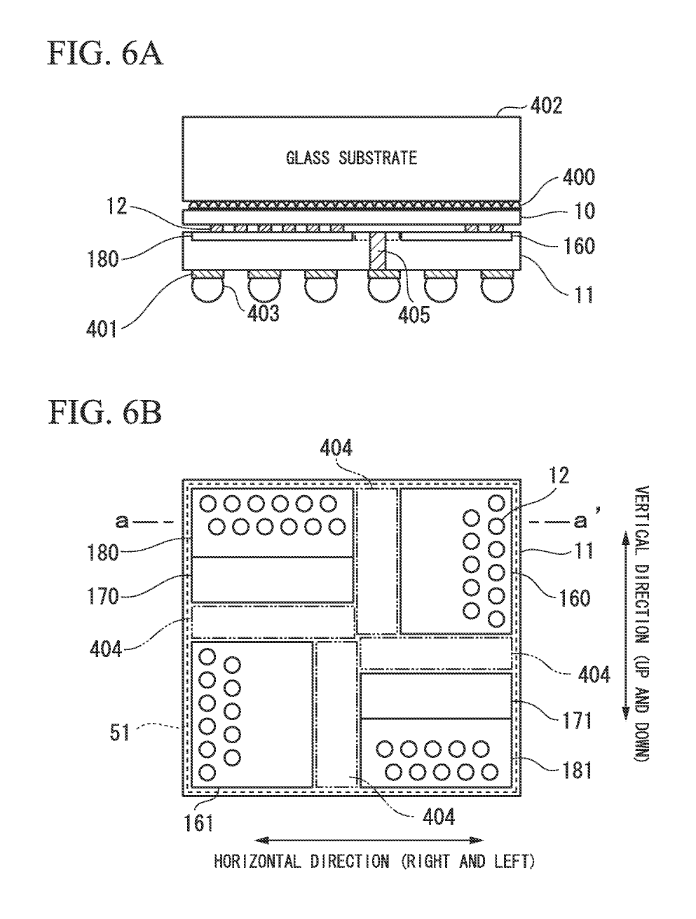

FIG. 6A is a sectional view illustrating a solid-state imaging device 22 according to this embodiment. FIG. 6B is a plan view illustrating the planar configuration of the second substrate 11 of the solid-state imaging device 22. The right and left directions in FIG. 6B are referred to as a horizontal direction and the upper and low directions are referred to as a vertical direction. To facilitate the description of the positions of regions in the second substrate 11, sides in the horizontal direction are referred to as right and left sides and sides in the vertical direction are referred to as upper and lower sides.

FIG. 6A is a sectional view taken along the line a-a′ of the solid-state imaging device 22 shown in FIG. 6B. As shown in the drawing, connection portions 12 are formed between the first substrate 10 and the second substrate 11. Of the two main surfaces of the first substrate 10, a micro-lens 400 and a glass substrate 402 are disposed on the main surface (the main surface opposite the second substrate) to which light is emitted. Of the main surfaces of the second substrate 11, a first column-processing circuit 180, a first vertical scanning circuit 160, and a through-electrode region 404 are provided in the portion taken along the line a-a′ of the main surface on the side of the first substrate 10. Of the main surfaces of the second substrate 11, rear electrodes 401 and protruding electrodes 403 are formed on the main surface opposite the first substrate 10. Further, the substrate through-electrode 405 is formed to electrically connect the through-electrode region 404 to the rear-surface electrode 401.

FIG. 6B is a plan view illustrating the planar configuration of the second substrate 11 of the solid-state imaging device 22. As shown in the drawing, of the main surfaces of the second substrate 11, the first vertical scanning circuit 160, the second vertical scanning circuit 161, the first horizontal scanning circuit 170, the second horizontal scanning circuit 171, the first column-processing circuit 180, the second column-processing circuit 181, and the through-electrode region 404 are formed on the main surface on the side of the first substrate 10.

In the illustrated example, the first vertical scanning circuit 160 is formed in a right upper region of the region of the second substrate 11. The second vertical scanning circuit 161 is formed in a left lower region of the region of the second substrate 11. The first column-processing circuit 180 is formed in a left upper region of the region of the second substrate 11. The second column-processing circuit 181 is formed in a right lower region of the region of the second substrate 11. The first horizontal scanning circuit 170 is formed in a region on the lower side of the first column-processing circuit 180 in the region of the second substrate 11. The second horizontal scanning circuit 171 is formed in a region on the upper side of the second column-processing circuit 181 in the region of the second substrate 11. The first vertical scanning circuit 160, the second vertical scanning circuit 161, the first horizontal scanning circuit 170, the second horizontal scanning circuit 171, the first column-processing circuit 180, and the second column-processing circuit 181 are connected to each other by the connection portions 12.

In the region of the second substrate 11, the through-electrode region 404 is formed in regions between the first vertical scanning circuit 160 and the second horizontal scanning circuit 171, between the first vertical scanning circuit 160, and the first column-processing circuit 180 and the first horizontal scanning circuit 170, between the second vertical scanning circuit 161 and the first horizontal scanning circuit 170, and between the second vertical scanning circuit 161, and the second column-processing circuit 181 and the second horizontal scanning circuit 171. The arrangement of the first vertical scanning circuit 160, the second vertical scanning circuit 161, the first horizontal scanning circuit 170, the second horizontal scanning circuit 171, the first column-processing circuit 180, the second column-processing circuit 181, and the through-electrode region 404 is not limited thereto. Any arrangement thereof may be realized, as long as these circuits and the through-electrode region are within the region of the second substrate 11.

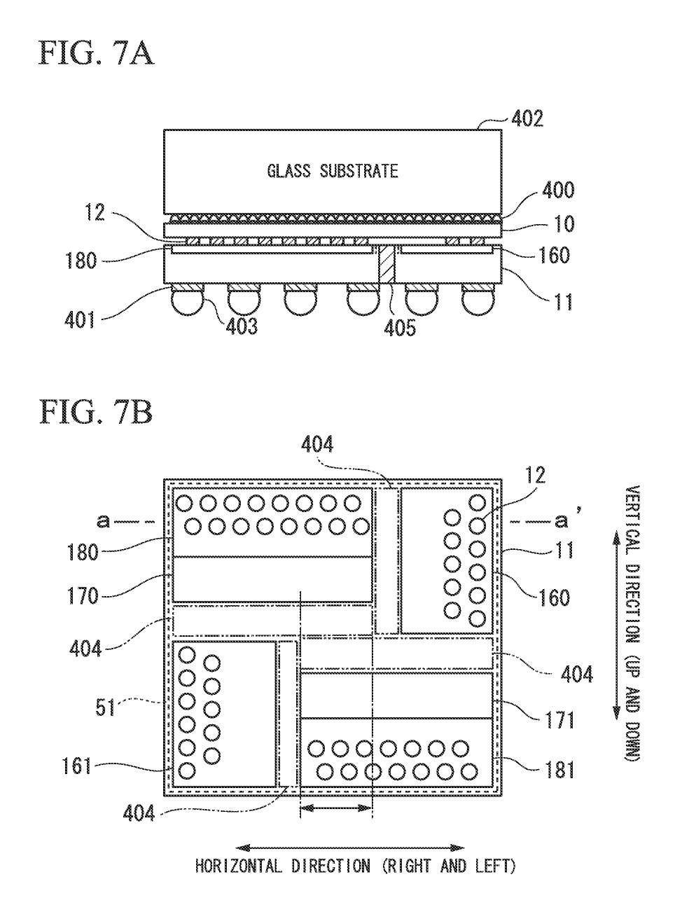

FIG. 7A is a sectional view illustrating the solid-state imaging device 22. FIG. 7B is a plan view illustrating the planar configuration of the second substrate 11 of the solid-state imaging device 22. A difference between the examples of FIGS. 6A and 6B is the arrangement of the first vertical scanning circuit 160, the second vertical scanning circuit 161, the first horizontal scanning circuit 170, the second horizontal scanning circuit 171, the first column-processing circuit 180, the second column-processing circuit 181, and the through-electrode region 404 in the region of the second substrate 11.

In the example of FIG. 7B, the first horizontal scanning circuit 170 and the second horizontal scanning circuit 171 are arranged in a region overlapping when viewed in the horizontal direction, unlike the example of FIG. 6B. That is, the first horizontal scanning circuit 170 and the second horizontal scanning circuit 171 overlap each other in the horizontal direction. Likewise, the first column-processing circuit 180 and the second column-processing circuit 181 are arranged in a region overlapping when viewed in the horizontal direction. Thus, the first horizontal scanning circuit 170 and the second horizontal scanning circuit 171 may be arranged to overlap each other in the horizontal direction. Further, the first column-processing circuit 180 and the second column-processing circuit 181 may be arranged to overlap each other in the horizontal direction. In the illustrated example, the first column-processing circuit 180 and the second column-processing circuit 181 are arranged not to overlap each other when viewed in the vertical direction, but the present embodiment is not limited thereto. The first column-processing circuit 180 and the second column-processing circuit 181 may be arranged to overlap each other in the vertical direction.

According to this embodiment, as described above, the substrate through electrodes 405, the rear-surface electrodes 401, and the protruding electrode 403 are formed in the second substrate 11 to be electrically connected to the outside. Accordingly, since it is not necessary to provide the pads 101 formed in the solid-state imaging device 2 according to the first embodiment in the main surface of the first substrate 10, it is possible to increase the occupation area ratio of the pixels 201 to the chip size (the surface area of a chip) of the solid-state imaging device 22. Further, the cheap and miniaturized solid-state imaging device 22 can be provided by adhering the micro-lens and the glass substrate to the main surface (the main surface opposite the second substrate) to which light is emitted of the two main surfaces of the first substrate 10, and then performing dicing and packaging in a process of manufacturing the solid-state imaging device 22.

### Third Embodiment

Next, a third embodiment of the present invention will be described with reference to the drawings. A difference between the configurations of a solid-state imaging device of this embodiment and the solid-state imaging device 2 of the first embodiment is as follows. That is, in this embodiment, a first substrate 10, a second substrate 11, and a third substrate 13 are stacked. Pixels are disposed astride the first substrate 10 and the second substrate 11.

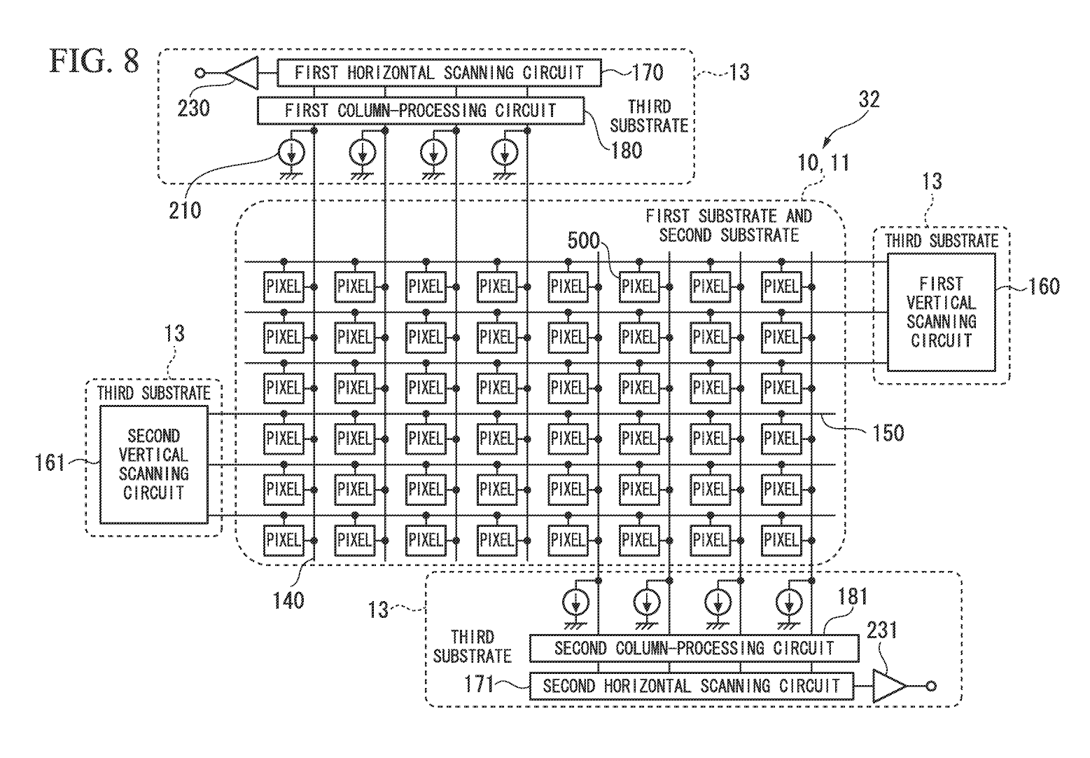

FIG. 8 is a block diagram illustrating the configuration of a solid-state imaging device 32 according to this embodiment. In the illustrated example, the solid-state imaging device 32 includes a plurality of pixels 500, a first vertical scanning circuit 160, a second vertical scanning circuit 161, a first horizontal scanning circuit 170, a second horizontal scanning circuit 171, a first column-processing circuit 180, a second column-processing circuit 181, a vertical signal line current source 210, and output amplifiers 230 and 231.

In this embodiment, the solid-state imaging device 32 includes three substrates, the first substrate 10, the second substrate 11, and the third substrate 13. The first substrate 10, the second substrate 11, and the third substrate 13 are stacked. The first substrate 10 and the second substrate 11 are electrically connected to the each other by connection portions. The second substrate 11 and the third substrate 13 are electrically connected to each other by connection portions. The pixels 500 are formed astride the first substrate 10 and the second substrate 11. The first vertical scanning circuit 160, the second vertical scanning circuit 161, the first horizontal scanning circuit 170, the second horizontal scanning circuit 171, the first column-processing circuit 180, the second column-processing circuit 181, the vertical signal line current source 210, and the output amplifiers 230 and 231 are formed in the third substrate 13. The disposition positions of the illustrated circuit constituent elements do not necessarily accord with the actual disposition positions of the circuit constituent elements.

The pixel 500 includes a photoelectric conversion element and a memory. A pixel signal output by the pixel 500 is a unit partition signal for extracting a digital signal when the solid-state imaging device 32 captures an image. In the illustrated example, forty-eight pixels 500 are arrayed in six rows and eight columns, but the array of the pixels 500 is merely an example. The number of rows and the number of columns may be one or more. In the illustrated example, the pixels 500 arrayed in the matrix form are schematically illustrated, and the pixels 500 are not disposed separately.

In this embodiment, a region of all the pixels 500 included in the solid-state imaging device 32 is configured as a reading target region of a pixel signal, but part of the region of all the pixels 500 included in the solid-state imaging device 32 may be configured as the reading target region. The reading target region preferably includes at least all of the pixels 500 of an effective pixel region. The reading target region may include optical black pixels (pixels from which light is normally shielded) disposed outside the effective pixel region.

A pixel signal read from the optical black pixel is, for example, used to correct a dark current component.

The first vertical scanning circuit 160, the second vertical scanning circuit 161, the first horizontal scanning circuit 170, the second horizontal scanning circuit 171, the first column-processing circuit 180, the second column-processing circuit 181, the vertical signal line current source 210, and the output amplifiers 230 and 231 included in the solid-state imaging device 32 are the same as those of the solid-state imaging device 2 of the first embodiment.

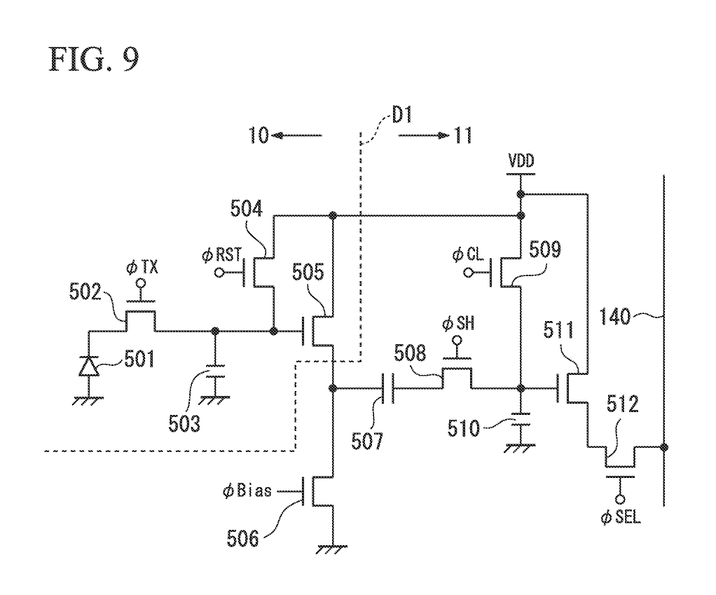

FIG. 9 is a diagram illustrating the circuit configuration of the pixel 500. The pixel 500 includes a photoelectric conversion element 501, a transmission transistor 502, a floating diffusion (FD) 503, an FD reset transistor 504, a first amplification transistor 505, a load transistor 506, a clamp capacitor 507, a sample transistor 508, an analog memory reset transistor 509, an analog memory 510, a second amplification transistor 511, and a select transistor 512. The disposition positions of the circuit constituent elements illustrated in FIG. 9 do not necessarily accord with the actual disposition positions of the circuit constituent elements. In the illustrated example, one analog memory 510 is provided in one photoelectric conversion element 501, but the present embodiment is not limited thereto. The plurality of photoelectric conversion elements 501 may be configured to share one analog memory 510.

One end of the photoelectric conversion element 501 is grounded. A drain terminal of the transmission transistor 502 is connected to the other end of the photoelectric conversion element 501. A gate terminal of the transmission transistor 502 is connected to the first vertical scanning circuit 160 or the second vertical scanning circuit 161, and thus a transmission pulse φTX is supplied. One end of the FD 503 is connected to a source terminal of the transmission transistor 502 and the other end of the FD 503 is grounded. A drain terminal of the FD reset transistor 504 is connected to a supply voltage VDD and a source terminal of the FD reset transistor 504 is connected to the source terminal of the transmission transistor 502. A gate terminal of the FD reset transistor 504 is connected to the first vertical scanning circuit 160 or the second vertical scanning circuit 161, and thus an FD reset pulse φRST is supplied.

A drain terminal of the first amplification transistor 505 is connected to the supply voltage VDD. A gate terminal, which is an input portion of the first amplification transistor 505, is connected to the source terminal of the transmission transistor 502. A drain terminal of the load transistor 506 is connected to a source terminal of the first amplification transistor 505, and a source terminal of the load transistor 506 is grounded. A gate terminal of the load transistor 506 is connected to the first vertical scanning circuit 160 or the second vertical scanning circuit 161, and thus a current control pulse φBias is supplied.

One end of the clamp capacitor 507 is connected to the source terminal of the first amplification transistor 505 and the drain terminal of the load transistor 506. A drain terminal of the sample transistor 508 is connected to the other end of the clamp capacitor 507. A gate terminal of the sample transistor 508 is connected to the first vertical scanning circuit 160 or the second vertical scanning circuit 161, and thus a sample pulse φSH is supplied.

A drain terminal of the analog memory reset transistor 509 is connected to the supply voltage VDD and a source terminal of the analog memory reset transistor 509 is connected to a source terminal of the sample transistor 508. A gate terminal of the analog memory reset transistor 509 is connected to the first vertical scanning circuit 160 or the second vertical scanning circuit 161, and thus a clamp & memory reset pulse φCL is supplied.

One end of the analog memory 510 is connected to the source terminal of the sample transistor 508 and the other end of the analog memory 510 is grounded. A drain terminal of the second amplification transistor 511 is connected to the supply voltage VDD. A gate terminal forming the input portion of the second amplification transistor 511 is connected to the source terminal of the sample transistor 508. A drain terminal of the select transistor 512 is connected to a source terminal of the second amplification transistor 511 and a source terminal of the select transistor 512 is connected to the vertical signal line 140.

A gate terminal of the select transistor 512 is connected to the first vertical scanning circuit 160 or the second vertical scanning circuit 161, and thus a select pulse φSEL is supplied. The source and drain terminals may be reversed by reversing the polarity of each of the above-described transistors.

The photoelectric conversion element 501 is, for example, a photodiode. The photoelectric conversion element 501 generates (creates) a signal charge based on incident light, and retains and stores the generated (created) signal charge. The transmission transistor 502 is a transistor that transmits the signal charge stored in the photoelectric conversion element 501 to the FD 503. The On/Off of the transmission transistor 502 is controlled by the transmission pulse φTX from the first vertical scanning circuit 160 or the second vertical scanning circuit 161. The FD 503 is a capacitor that temporarily retains and stores the signal charge transmitted from the photoelectric conversion element 501.

The FD reset transistor 504 is a transistor that resets the FD 503.

The On/Off of the FD reset transistor 504 is controlled by the FD reset pulse φRST from the first vertical scanning circuit 160 or the second vertical scanning circuit 161. The photoelectric conversion element 501 can be reset by simultaneously turning on the FD reset transistor 504 and the transmission transistor 502. Resets of the FD 503 or the photoelectric conversion element 501 is to control the amount of charge stored in the FD 503 or the photoelectric conversion element 501 and set the state (potential) of the FD 503 or the photoelectric conversion element 501 to a reference state (a reference potential or a reset level).

The first amplification transistor 505 is a transistor that outputs an amplified signal obtained by amplifying a signal, which is input to its gate terminal and is based on the signal charge stored in the FD 503, from its source terminal. The load transistor 506 is a transistor that functions as the load of the first amplification transistor 505 and supplies a current for driving the first amplification transistor 505 to the first amplification transistor 505. The On/Off of the load transistor 506 is controlled by the current control pulse φBias from the first vertical scanning circuit 160 or the second vertical scanning circuit 161. The first amplification transistor 505 and the load transistor 506 form a source follower circuit.

The clamp capacitor 507 is a capacitor that clamps (fixes) the voltage level of an amplification signal output from the first amplification transistor 505. The sample transistor 508 is a transistor that samples and holds the voltage level of the other end of the clamp capacitor 507 and stores the voltage level in the analog memory 510. The On/Off of the sample transistor 508 is controlled by the sample pulse φSH from the first vertical scanning circuit 160 or the second vertical scanning circuit 161.

The analog memory reset transistor 509 is a transistor that resets the analog memory 510. A reset of the analog memory 510 is to control the amount of charge stored in the analog memory 510 and set the state (potential) of the analog memory 510 to a reference state (a reference potential or a reset level). The analog memory 510 retains and stores the analog signal sampled and held by the sample transistor 508.

The capacitor of the analog memory 510 is set to be larger than the capacitor of the FD 503. In the analog memory 510, a metal insulator metal (MIM) capacitor or a metal oxide semiconductor (MOS) capacitor, which is a capacitor with a leakage current (dark current) small per unit area, is preferably used. Thus, the tolerance to noise is improved and a high-quality signal can be obtained.

The second amplification transistor 511 is a transistor that outputs an amplified signal obtained by amplifying a signal based on the signal charge input to its gate terminal and stored in the analog memory 510 from its source terminal. The second amplification transistor 511 and a current source (not shown) which is connected to the vertical signal line 140 and becomes a load form a source follower circuit. The select transistor 512 is a transistor that selects the pixel 500 and delivers the output of the second amplification transistor 511 to the vertical signal line 140. The On/Off of the select transistor 512 is controlled by the select pulse φSEL from the first vertical scanning circuit 160 or the second vertical scanning circuit 161.

Of the circuit constituent elements shown in FIG. 9, the photoelectric conversion element 501 is disposed in the first substrate 10, the analog memory 510 is disposed in the second substrate 11, and the other circuit constituent elements are disposed in one of the first substrate 10 and the second substrate 11. A dashed line D1 in FIG. 9 indicates a boundary between the first substrate 10 and the second substrate 11. In the illustrated example, the photoelectric conversion element 501, the transmission transistor 502, the FD 503, the FD reset transistor 504, and the first amplification transistor 505 are disposed in the first substrate 10. The load transistor 506, the clamp capacitor 507, the sample transistor 508, the analog memory reset transistor 509, the analog memory 510, the second amplification transistor 511, and the select transistor 512 are disposed in the second substrate 11.

An amplified signal output from the first amplification transistor 505 in the first substrate 10 is output to the second substrate 11 via the connection portion 12. The supply voltage VDD is transmitted and received between the first substrate 10 and the second substrate 11 via the connection portion 12.

In FIG. 9, the connection portion 12 is disposed in the path between the source terminal of the first amplification transistor 505, and the drain terminal of the load transistor 506 and one end of the clamp capacitor 507, but the present embodiment is not limited thereto. The connection portion 12 may be disposed at any position on an electrically connected path between the photoelectric conversion element 501 and the analog memory 510.

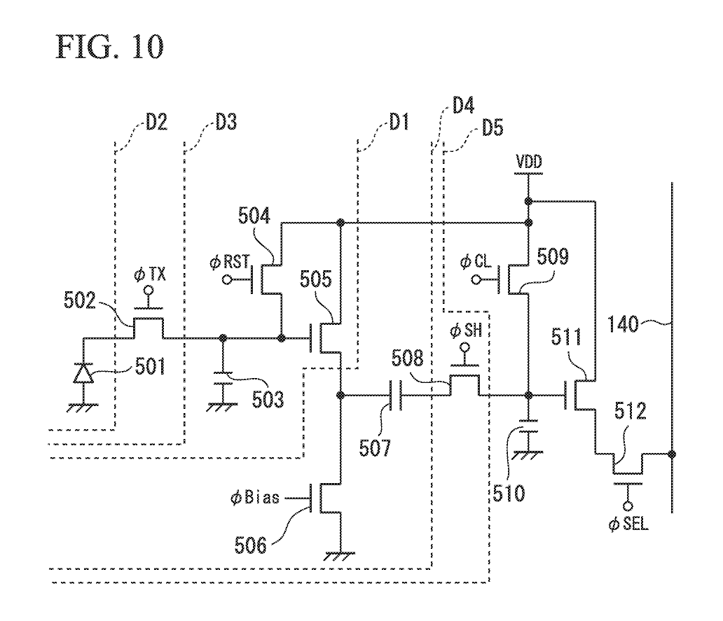

FIG. 10 is a diagram illustrating examples of a boundary line between the first substrate 10 and the second substrate 11. Dashed lines D1 to D5 indicate examples of a line usable as the boundary line between the first substrate 10 and the second substrate 11. The boundary line between the first substrate 10 and the second substrate 11 may be one of the dashed lines D1 to D5 or may be a line other than the dashed lines D1 to D5. The dashed line D1 is the above-described line. In the example indicated by the dashed line D2, the connection portion 12 is disposed in a path between the other end of the photoelectric conversion element 501 and the drain terminal of the transmission transistor 502. In the example indicated by the dashed line D3, the connection portion 12 is disposed in a path between the source terminal of the transmission transistor 502, and one end of the FD 503, the source terminal of the FD reset transistor 504, and the gate terminal of the first amplification transistor 505.

In the example indicated by the dashed line D4, the connection portion 12 is disposed in a path between the other end of the clamp capacitor 507 and the drain terminal of the sample transistor 508. In the example indicated by the dashed line D5, the connection portion 12 is disposed in a path between the source terminal of the sample transistor 508, and the source terminal of the analog memory reset transistor 509, one end of the analog memory 510, and the gate terminal of the second amplification transistor 511.

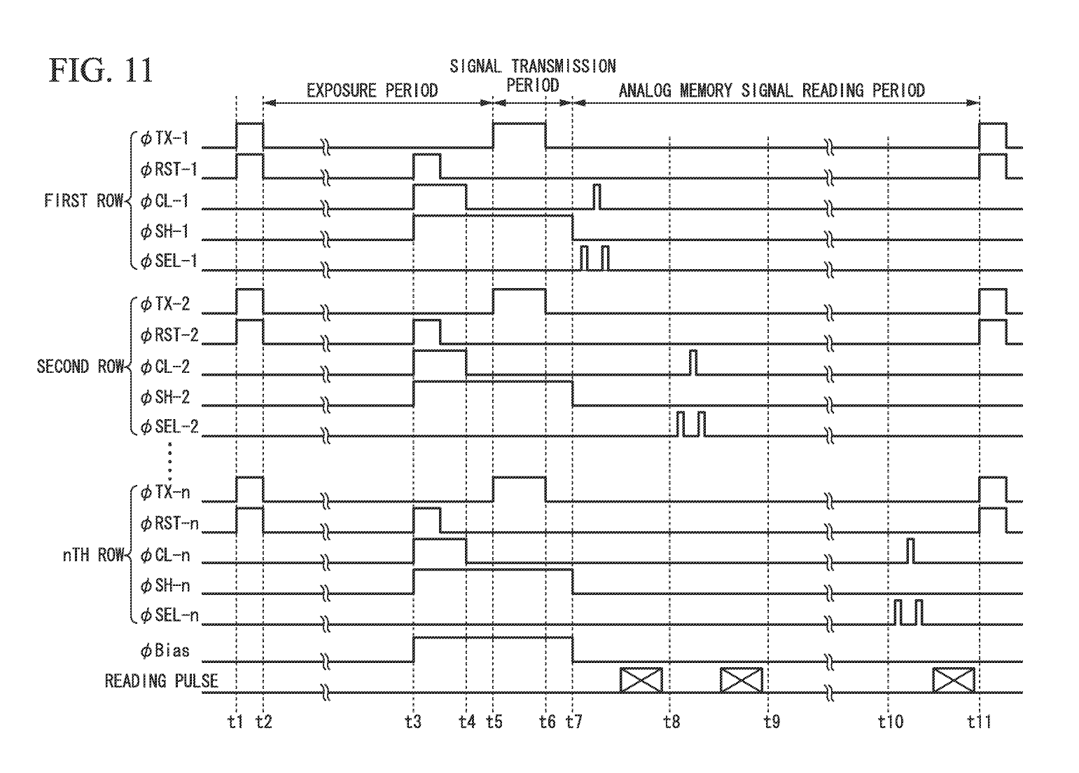

Next, the process of the pixel 500 will be described with reference to FIG. 11. FIG. 11 is a diagram illustrating control signals supplied for each row from the first vertical scanning circuit 160 or the second vertical scanning circuit to the pixels 500, the current control pulse φBias supplied collectively (simultaneously) to the pixels 500 of all the rows, and a reading pulse for reading a signal from the first horizontal scanning circuit 170 or the second horizontal scanning circuit 171 to the row control line 150. Hereinafter, the description will be made by adding a suffix indicating a row number to the control signal. For example, the transmission pulse φTX output to the pixels 500 of the first row is indicated by φTX-1. When a control signal of any row is indicated, the description will be made by adding i as a suffix indicating a row number. For example, the transmission pulse φTX output to the pixels 500 of all the rows, that is, all of the pixels 500 (hereinafter referred to as all the pixels) is representatively indicated by φTX-i.

At a time t1, when the transmission pulse φTX-i output to all the pixels is changed from an “L” (Low) level to an “H” (High) level, the transmission transistors 502 of all the pixels are turned on. Simultaneously, when the FD reset pulse φRST-i output to all the pixels is changed from the “L” level to the “H” level, the FD reset transistors 504 of all the pixels are turned on. Thus, the photoelectric conversion elements 501 are reset.

Subsequently, at time t2, when the transmission pulse φTX-i and the FD reset pulse φRST-i output to all the pixels are changed from the “H” level to the “L” level, the transmission transistors 502 and the FD reset transistors 504 of all the pixels are turned off. Thus, the resetting of the photoelectric conversion elements 501 ends and exposure (storage of the signal charge) on all the pixels collectively (simultaneously) starts.

At a time t3 within an exposure period, when the FD reset pulse φRST-i output to all the pixels is changed from the “L” level to the “H” level, the FD reset transistors 504 of all the pixels are turned on. Thus, the FDs 503 of all the pixels are reset. Simultaneously, when the current control pulse φBias output to all the pixels is changed from the “L” level to the “H” level, the load transistors 506 of all the pixels are turned on. Thus, the driving current is supplied to the first amplification transistors 505 and the first amplification transistors 505 start an amplification process.

Simultaneously, when the clamp & memory reset pulse φCL-i output to all the pixels is changed from the “L” level to the “H” level, the analog memory reset transistors 509 of all the pixels are turned on. Thus, the analog memories 510 of all the pixels are reset. Simultaneously, when the sample pulse φSH-i output to all the pixels is changed from the “L” level to the “H” level, the sample transistors 508 of all the pixels are turned on. Thus, the potentials of the other ends of the clamp capacitors 507 are reset to the supply voltage VDD, and the sample transistors 508 start sampling and holding the potentials of the other ends of the clamp capacitors 507.

Subsequently, when the FD reset pulse φRST-i output to all the pixels is changed from the “H” level to the “L” level, the FD reset transistors 504 of all the pixels are turned off. Thus, the resetting of the FDs 503 of all the pixels ends. The reset timing of the FDs 503 may be within the exposure period. However, by resetting the FDs 503 at a timing immediately before the end of the exposure period, noise caused due to the leakage current of the FDs 503 can be reduced more.

Subsequently, at a time t4 within the exposure period, when the clamp & memory reset pulse φCL-i output to all the pixels is changed from the “H” level to the “L” level, the analog memory reset transistors 509 of all the pixels are turned off. Thus, the resetting of the analog memories 510 of all the pixels ends. At this time point, the clamp capacitors 507 clamp the amplified signal (the amplified signal after the FDs 503 are reset) output from the first amplification transistors 505.

Subsequently, at a time t5, when the transmission pulse φTX-i output to all the pixels is changed from the “L” level to the “H” level, the transmission transistors 502 of all the pixels are turned on. Thus, the signal charges stored in the photoelectric conversion elements 501 of all the pixels are transmitted to the FDs 503 via the transmission transistors 502 and are stored in the FDs 503. As shown in FIG. 11, a period from the time t2 to the time t5 is the exposure period.

Subsequently, at a time t6, when the transmission pulse φTX-i output to all the pixels is changed from the “H” level to the “L” level, the transmission transistors 502 of all the pixels are turned off. Thus, the exposure (storage of the signal charges) on all the pixels collectively (simultaneously) ends.

Subsequently, at a time t7, when the sample pulse φSH-i output to all the pixels is changed from the “H” level to the “L” level, the sample transistors 508 of all the pixels are turned off. Thus, the sample transistors 508 end the sampling and holding of the potentials of the other ends of the clamp capacitors 507. Simultaneously, when the current control pulse φBias output to all the pixels is changed from the “H” level to the “L” level, the load transistors 506 of all the pixels are turned off. Thus, the supply of the driving current to the first amplification transistor 505 is stopped, and the first amplification transistors 505 stop the amplification process. As shown in FIG. 11, a period from the time t5 to the time t7 is a signal transmission period.

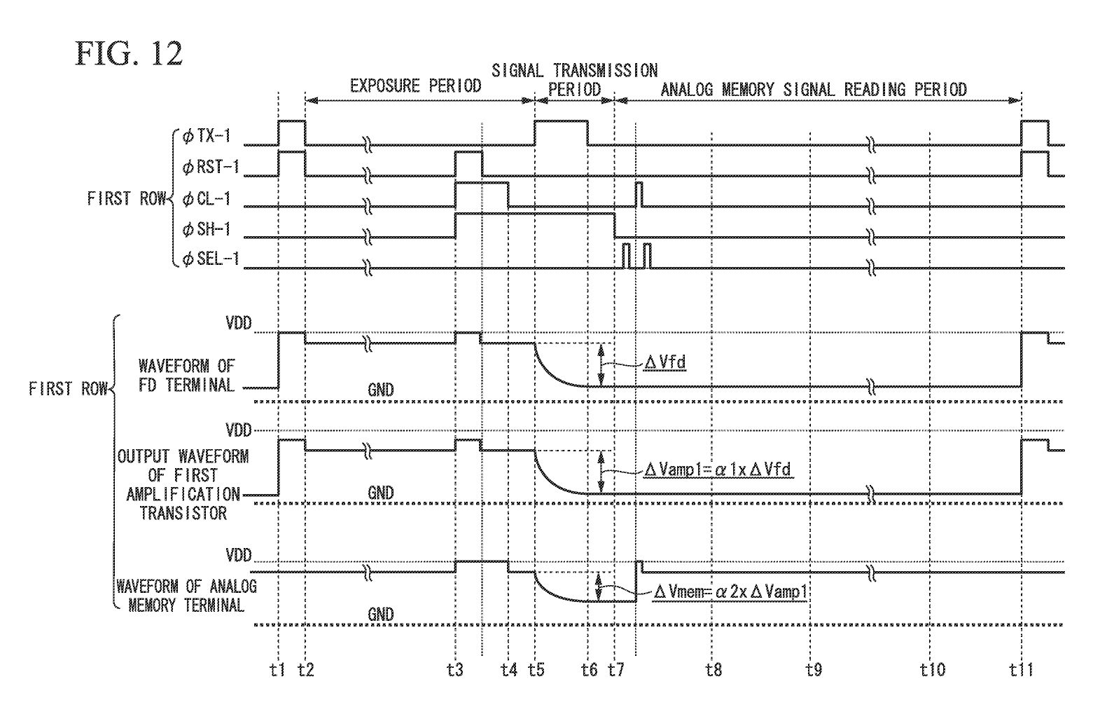

FIG. 12 is a diagram illustrating the control signals supplied from the first vertical scanning circuit 160 or the second vertical scanning circuit 161 to the pixels 500 of the first row, the potential of one end of the FD 503, the potential of the source terminal of the first amplification transistor 505, and the potential of one end of the analog memory 510.

When it is assumed that ΔVfd is a change in the potential of one end of the FD 503 caused by the transmission of the signal charge from the photoelectric conversion element 501 to the FD 503 after the end of the resetting of the FD 503 and al is the gain of the first amplification transistor 505, a change ΔVamp1 in the potential of the source terminal of the first amplification transistor 505 caused by the transmission of the signal charge from the photoelectric conversion element 501 to the FD 503 is α1×Vfd.

When it is assumed that α2 is the sum gain of the analog memory 510 and the sample transistor 508, a change ΔVmem in the potential of one end of the analog memory 510 caused by the sampling and holding of the sample transistor 508 after the transmission of the signal charge from the photoelectric conversion element 501 to the FD 503 is α2×ΔVamp1, that is, α1×α2×ΔVfd. Since the potential of one end of the analog memory 510 at the time of ending the resetting of the analog memory 510 is the supply voltage VDD, the potential Vmem of one end of the analog memory 510 sampled and held by the sample transistor 508 after the transmission of the signal charge from the photoelectric conversion element 501 to the FD 503 is expressed by Equation (1) below. In Equation (1), ΔVmem<0 and ΔVfd<0.

Vmem=VDD+ΔVmem=VDD+α1×α2ΔVfd (1)

Further, α2 is expressed by Equation (2). In Equation (2), CL indicates the capacitance of the clamp capacitor 507 and CSH indicates the capacitance of the analog memory 510. To further decrease the deterioration in the gain, the capacitance CL of the clamp capacitor 507 is preferably greater than the capacitance CSH of the analog memory 510.

$$α 2 = \frac{CL}{CL + CSH} \qquad ( 2 )$$

After a time t7, signals based on the signal charge stored in the analog memory 510 are sequentially read for each row. During a period from the time t7 to a time t8, the signals are read from the pixels 500 of the first row. First, when the select pulse φSEL-1 output to the pixels 500 of the first row is changed from the “L” level to the “H” level, the select transistors 112 of the pixels 500 of the first row are turned on. Thus, the signal based on the potential Vmem expressed by Equation (1) is output to the vertical signal line 140 via the select transistors 112. Subsequently, when the select pulse φSEL-1 output to the pixels 500 of the first row is changed from the “H” level to the “L” level, the select transistors 112 of the pixels 500 of the first row are turned off.

Subsequently, when the clamp & memory reset pulse φCL-1 output to the pixels 500 of the first row is changed from the “L” level to the “H” level, the analog memory reset transistors 509 of the pixels 500 of the first row are turned on. Thus, the analog memories 510 of the pixels 500 of the first row are reset. Subsequently, when the clamp & memory reset pulse φCL-1 output to the pixels 500 of the first row is changed from the “H” level to the “L” level, the analog memory reset transistors 509 of the pixels 500 of the first row are turned off.

Subsequently, when the select pulse φSEL-1 output to the pixels 500 of the first row is changed from the “L” level to the “H” level, the select transistors 112 of the pixels 500 of the first row are turned on. Thus, the signals based on the potentials of one ends of the analog memories 510 at the time of resetting the analog memories 510 are output to the vertical signal line 140 via the select transistors 112. Subsequently, when the select pulse φSEL-1 is changed from the “H” level to the “L” level, the select transistors 512 are turned off.

The first column-processing circuit 180 or the second column-processing circuit 181 generates a difference signal indicating a difference between the signal based on the potential Vmem expressed by Equation (1) and the signal based on the potential of one end of the analog memory 510 at the time of resetting the analog memory 510. The difference signal is a signal based on the difference between the potential Vmem expressed by Equation (1) and the supply voltage VDD, and is a signal based on the difference ΔVfd between the potential of one end of the FD 503 immediately after the transmission of the signal charge stored in the photoelectric conversion element 501 to the FD 503 and the potential of the FD 503 immediately after the resetting of one end of the FD 503. Accordingly, it is possible to obtain the signal component for which a noise component caused due to the resetting of the analog memory 510 and a noise component caused due to the resetting of the FD 503 are suppressed and which is based on the signal charge stored in the photoelectric conversion element 501.

The signals output from the first column-processing circuit 180 or the second column-processing circuit 181 are output to the row control line 150 by the first horizontal scanning circuit 170 or the second horizontal scanning circuit 171. The output amplifiers 230 and 231 process the signals output to the row control line 150 and output the processed signals as pixel signals. Then, the process of reading the signals from the pixels 500 of the first row ends.

During a period from a time t8 to a time t9, the signals are read from the pixels 500 of the second row. Since the process of reading the signals from the pixels 500 of the second row is the same as the process of reading the signals from the pixels 500 of the first row, the description thereof will not be repeated. The same process is performed on the pixels 500 of each row after the second row. During a period from a time t10 to a time t11, signals are read from the pixels 500 of the final row (n^{th} row). Since this process is the same as the process of reading the signals from the pixels 500 of the first row, the description thereof will not be repeated. After the process of reading the signals of all the pixels ends, the process is performed again from the time t1. In FIG. 11, the process is performed again from the time t1, after the process of reading the signals from all of the pixels ends. However, the process relevant to the pixels 500 may end after the process of reading the signals from all of the pixels ends.

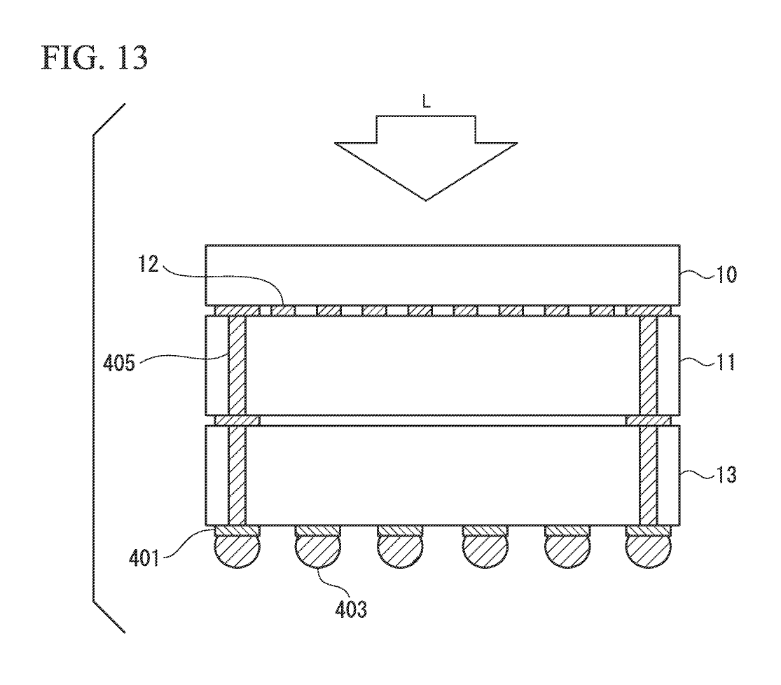

FIG. 13 is a sectional view illustrating the solid-state imaging device 32. In the illustrated example, the solid-state imaging device 32 includes the first substrate 10, the second substrate 11, the third substrate 13, and the connection portions 12.

The first substrate 10, the second substrate 11, and the third substrate 13 are sequentially stacked. Of the two main surfaces (the front surface with a larger surface area than the rear surface) of the first substrate 10, light L is emitted to the main surface opposite the second substrate 11.

The connection portions 12 are formed between the first substrate 10 and the second substrate 11 and between the second substrate 11 and the third substrate 13. In the second substrate 11, the substrate through electrodes 405 are formed to electrically connect the connection portions 12 coming into contact with two main surfaces of the second substrate 11 to each other. Of the main surfaces of the third substrate 13, the rear-surface electrodes 401 and the protruding electrodes 403 are formed on the main surface opposite the second substrate 11. In the third substrate 13, the substrate through electrodes 405 are formed to electrically connect the rear-surface electrodes 401 to the connection portions 12 coming into contact with the main surface of the third substrate 13. In this configuration, the first substrate 10, the second substrate 11, the third substrate 13, and the rear-surface electrodes 401 and the protruding electrodes 403 are electrically connected to each other.

According to this embodiment, as described above, the first substrate 10, the second substrate 11, and the third substrate 13 are stacked. Further, the first substrate 10, the second substrate 11, and the third substrate 13 are electrically connected to each other by the connection portions 12 and the substrate through electrodes 405. The pixels 500 are formed astride the first substrate 10 and the second substrate 11. In the region of the third substrate 13, the first vertical scanning circuit 160, the second vertical scanning circuit 161, the first horizontal scanning circuit 170, the second horizontal scanning circuit 171, the first column-processing circuit 180, the second column-processing circuit 181, the vertical signal line current source 210, and the output amplifiers 230 and 231 are formed in the overlapping region 51 overlapping in the vertical direction with the pixel region 50 in which the pixels 500 are formed in the first substrate 10 and the second substrate 11.

According to such a configuration, it is possible to increase the occupation area ratio of the pixels 500 to the chip area (the surface area of a chip) of the solid-state imaging device 32 without reduction in the circuit sizes of the first vertical scanning circuit 160, the second vertical scanning circuit 161, the first horizontal scanning circuit 170, the second horizontal scanning circuit 171, the first column-processing circuit 180, the second column-processing circuit 181, the vertical signal line current source 210, and the output amplifiers 230 and 231, that is, without deterioration in function.

In this embodiment, the pixels 500 are formed astride the first substrate 10 and the second substrate 11. The photoelectric conversion elements 501 of the pixels 500 are disposed at least in the first substrate 10.

Accordingly, it is possible to increase the occupation area ratio of the photoelectric conversion elements 501 of the pixels 500 to the chip area (the surface area of a chip) of the solid-state imaging device 32. Further, since the pixel 500 has the global shutter function, it is possible to realize the solid-state imaging device 32 having the global shutter function, while reducing the chip size of the solid state imaging device 32.

The embodiments of the present invention have been described in detail with reference to the drawings. However, the specific configurations are not limited to the above-described embodiments, but include modifications of the design within the scope of the present invention without departing from the gist of the present invention.

For example, in the solid-state imaging device according to the above-described embodiments, the case in which two substrates or three substrates are stacked has been exemplified, but the present embodiment is not limited thereto. The solid-state imaging device may be configured such that two or more substrates are stacked and the constituent elements are distributed and disposed in the substrates. In this case, of two main surfaces of the first substrate, the photodiodes of the pixels are disposed in the main surface to which light is emitted. For example, the solid-state imaging device may be configured such that the pixels are formed in the first substrate, the first and second vertical scanning circuits are formed in the second substrate, and the first and second horizontal scanning circuits and the first and second column-processing circuits are formed in the third substrate. Moreover, the solid-state imaging device may be configured such that the pixels are formed in the first substrate, the first and second horizontal scanning circuit and the first and second column-processing circuit are formed in the second substrate, and the first and second vertical scanning circuit are formed in the third substrate.

In the above-described configurations, in the region of a substrate other than the first substrate, the first and second vertical scanning circuits, the first and second horizontal scanning circuits, the first and second column-processing circuits, the vertical signal line current source, and the output amplifiers are formed in the overlapping region 51 overlapping in the vertical direction with the pixel region of the first substrate in which the pixels are formed, but the present invention is not limited to the configurations of the embodiments. For example, in the region of a substrate other than the first substrate, at least parts of the first and second vertical scanning circuits, the first and second horizontal scanning circuits, the first and second column-processing circuits, the vertical signal line current source, and the output amplifiers are formed in the overlapping region 51 overlapping in the vertical direction with the pixel region of the first substrate in which the pixels are formed.

For example, the solid-state imaging device according to an aspect of the present invention may be “a solid-state imaging device in which first to n^{th} (where n is an integer greater than or equal to 2) substrates are electrically connected to each other via connection portions and are stacked. An m^{th} (where m is an integer greater than or equal to 1 and less than or equal to n) substrate includes a pixel region which has pixels including a photoelectric conversion element. A substrate other than the m^{th} substrate includes a driving circuit including a circuit element provided to drive the pixel. In a region of the other substrate, at least a part of the driving circuit is disposed within an overlapping region overlapping the pixel region in a vertical direction.”

For example, the solid-state imaging device according to an aspect of the present invention may be “a solid-state imaging device in which first to n^{th} (where n is an integer greater than or equal to 2) substrates are electrically connected to each other via connection portions and are stacked. An m^{th} (where m is an integer greater than or equal to 1 and less than or equal to n) substrate includes a pixel region which has pixels including a photoelectric conversion element. A substrate other than the m^{th} substrate includes a reading circuit including a circuit element provided to read a signal output by the pixel. In a region of the other substrate, at least a part of the reading circuit is disposed within an overlapping region overlapping the pixel region in a vertical direction.”

For example, the imaging device according to an aspect of the present invention may be “an imaging device in which first to n^{th} (where n is an integer greater than or equal to 2) substrates are electrically connected to each other via connection portions and are stacked. An m^{th} (where m is an integer greater than or equal to 1 and less than or equal to n) substrate includes a pixel region which has pixels including a photoelectric conversion element. A substrate other than the m^{th} substrate includes driving means including a circuit element provided to drive the pixel. In a region of the other substrate, at least a part of the driving means is disposed within an overlapping region overlapping the pixel region in a vertical direction.”

For example, the imaging device according to an aspect of the present invention may be “an imaging device in which first to n^{th} (where n is an integer greater than or equal to 2) substrates are electrically connected to each other via connection portions and are stacked. An m^{th} (where m is an integer greater than or equal to 1 and less than or equal to n) substrate includes a pixel region which has pixels including a photoelectric conversion element. A substrate other than the m^{th} substrate includes reading means including a circuit element provided to read a signal output by the pixel. In a region of the other substrate, at least a part of the reading means is disposed within an overlapping region overlapping the pixel region in a vertical direction.”

A computer program product realizing any combination of the constituent elements and the processes described above is also effective as an aspect of the present invention. The computer program product refers to a recording medium, an apparatus, a device, or a system in which a program code is embedded, such as a recording medium (a DVD medium, a hard disk medium, a memory medium, and the like) recording a program code, a computer recording the program code, or an Internet system (for example, a system including a server and a client terminal) recording the program code. In this case, the constituent elements and the processes described above are mounted as modules and the program code formed by the mounted modules is recorded in the computer program product.

For example, the computer program product according to an aspect of the present invention may be “a computer program product recording a program code that causes a computer to execute to execute a process of driving a driving circuit of a solid-state imaging device. In the solid-state imaging device, first to n^{th} (where n is an integer greater than or equal to 2) substrates are electrically connected to each other via connection portions and are stacked. An m^{th} (where m is an integer greater than or equal to 1 and less than or equal to n) substrate includes a pixel region which has pixels including a photoelectric conversion element. A substrate other than the m^{th} substrate includes the driving circuit including a circuit element provided to drive the pixel. In a region of the other substrate, at least a part of the driving circuit is disposed within an overlapping region overlapping the pixel region in a vertical direction.”

For example, the computer program product according to an aspect of the present invention may be “a computer program product recording a program code that causes a computer to execute a process of driving a reading circuit of a solid-state imaging device. In the solid-state imaging device, first to n^{th} (where n is an integer greater than or equal to 2) substrates are electrically connected to each other via connection portions and are stacked. An m^{th} (where m is an integer greater than or equal to 1 and less than or equal to n) substrate includes a pixel region which has pixels including a photoelectric conversion element. A substrate other than the m^{th} substrate includes the reading circuit including a circuit element provided to read a signal output by the pixel. In a region of the other substrate, at least a part of the reading circuit is disposed within an overlapping region overlapping the pixel region in a vertical direction.”

A program realizing any combination of the constituent elements and the processes described above is also effective as aspects of the present invention. The objects of the present invention can be achieved by recording the program in a computer-readable recording medium, causing a computer to read the program recorded on the recording medium, and executing the program.

Here, the term “computer” includes home page-providing environments (or display environments) when a WWW system is used. Further, the term “computer-readable recording medium” refers to a transportable medium such as a flexible disk, a magneto-optical disc, a ROM, and a CD-ROM or a storage device such as a hard disk included in a computer. Furthermore, the term “computer-readable recording medium” includes a medium that holds the program for a given time, such as a volatile memory (RAM) included in a computer system such as a server or a client when the program is transmitted via a network such as the Internet or a communication link such as a telephone link.

The above-described program may be transmitted from a computer storing the program in a storage device or the like to another computer via a transmission medium or by transmission waves in a transmission medium. Here, the term “transmission medium” transmitting the program refers to a medium that has a function of transmitting information, such as a network (communication network) such as the Internet or a communication link (communication line) such as a telephone link. The above-described program may be a program configured to realize some of the above-described functions. Further, the program may be a so-called difference file (difference program) in which the above-described functions are realized by combination with a program already recorded in a computer.

The preferred embodiments of the present invention have been described, but various substitutions, modifications, or equivalents can be used as the above-described constituent elements or processes. In the embodiments disclosed in the present specification, a single component may be substituted with a plurality of components or a plurality of components may be substituted with a single component in order to perform one or a plurality of the functions. The substitutions are within the scope of the present invention excluding a case in which the substitution does not appropriately operate to achieve the objects of the present invention. Accordingly, the scope of the present invention is not determined with reference to the above description, but should be determined by the claims, and the entire scope of equivalents is also included. In the claims, one or more of each constituent element may be included, unless explicitly stated otherwise. The claims should not be construed as inclusion of the limitation of a means-plus-function, excluding a case in which the term “means for” is explicitly included in the claims.

The terminologies used in the present specification are used to describe specific embodiments, and thus are not intended to limit the present invention. In the present specification, even when a particular terminology is used in the singular, the terminology includes a plural form unless the plural form thereof is explicitly excluded in the context. The present invention is not limited to the above description, but is limited only by the scope of the accompanying claims.

What is claimed is:

1. A solid-state imaging device, comprising:
first to n^{th} substrates being electrically connected to each other via connection portions and being stacked,
wherein an m^{th} substrate includes a pixel region which has pixels including a photoelectric conversion element,
wherein a substrate other than the m^{th} substrate includes a driving circuit including a circuit element provided to drive the pixel,
wherein, in a region of the other substrate, at least a part of the driving circuit is disposed within an overlapping region overlapping the pixel region in a vertical direction, and
wherein n is an integer greater than or equal to 2 and m is an integer greater than or equal to 1 and less than or equal to n.

2. The solid-state imaging device according to claim 1, wherein the driving circuit is a vertical scanning circuit.

3. The solid-state imaging device according to claim 2,
wherein the vertical scanning circuit includes unit circuits arrayed in the vertical direction in a number necessary to drive all of the pixels, and
wherein the vertical scanning circuit is divided into a plurality of vertical circuit blocks.

4. The solid-state imaging device according to claim 3, wherein the divided vertical circuit blocks are shifted and disposed in at least one of a horizontal direction and the vertical direction.

5. The solid-state imaging device according to claim 3, wherein the divided vertical circuit blocks are shifted and disposed so as not to overlap each other.

6. The solid-state imaging device according to claim 3, wherein the divided vertical circuit blocks are disposed so as to have a positional relationship in which parts of the vertical circuit blocks overlap each other when viewed in the horizontal direction.

7. The solid-state imaging device according to claim 4, wherein the plurality of vertical circuit blocks are disposed to be included in the overlapping region.

8. The solid-state imaging device according to claim 7, wherein a substrate through-electrode penetrating through the substrate is formed in a location other than the locations at which the vertical circuit blocks are disposed in the overlapping region.

9. The solid-state imaging device according to claim 1, wherein a substrate through-electrode penetrating through the substrate is formed in at least one substrate of the first to n^{th} substrates.

10. The solid-state imaging device according to claim 9, wherein the first to n^{th} substrates are stacked in order and an electrode portion exchanging a signal with the outside is formed in a rear surface of the n^{th} substrate.

11. The solid-state imaging device according to claim 10, wherein the substrate through-electrode is connected to the electrode portion formed in the rear surface of the n^{th} substrate.

12. The solid-state imaging device according to claim 1, wherein a glass substrate is adhered and joined to a surface of the first substrate on which light is incident.

13. The solid-state imaging device according to claim 1,
wherein the driving circuit is formed in the second substrate, and
wherein a reading circuit is formed from the third to n^{th} substrates.

14. The solid-state imaging device according to claim 1, wherein the driving circuit included in another substrate includes a signal storage unit that stores a signal generated by the photoelectric conversion element included in the m^{th} substrate and input via the connection portion.

15. The solid-state imaging device according to claim 14,
wherein another substrate includes a reading circuit that includes a circuit element provided to read a signal output by the pixel, and
wherein the reading circuit reads the signal stored by the signal storage unit.

16. The solid-state imaging device according to claim 15, wherein, in a region of the other substrate, at least a part of the reading circuit is disposed in the overlapping region overlapping the pixel region in the vertical direction.

17. A solid-state imaging device, comprising:
first to n^{th} substrates being electrically connected to each other via connection portions and being stacked,
wherein an m^{th} substrate includes a pixel region which has pixels including a photoelectric conversion element,
wherein a substrate other than the m^{th} substrate includes a reading circuit including a circuit element provided to read a signal output by the pixel,
wherein, in a region of the other substrate, at least a part of the reading circuit is disposed within an overlapping region overlapping the pixel region in a vertical direction, and
wherein n is an integer greater than or equal to 2 and m is an integer greater than or equal to 1 and less than or equal to n.

18. An imaging device, comprising:
first to n^{th} substrates being electrically connected to each other via connection portions and being stacked,
wherein an m^{th} substrate includes a pixel region which has pixels including a photoelectric conversion element,
wherein a substrate other than the m^{th} substrate includes a driving circuit including a circuit element provided to drive the pixel,
wherein, in a region of the other substrate, at least a part of the driving circuit is disposed within an overlapping region overlapping the pixel region in a vertical direction, and
wherein n is an integer greater than or equal to 2 and m is an integer greater than or equal to 1 and less than or equal to n.

19. An imaging device, comprising
first to n^{th} substrates being electrically connected to each other via connection portions and being stacked,
wherein an m^{th} substrate includes a pixel region which has pixels including a photoelectric conversion element,
wherein a substrate other than the m^{th} substrate includes a reading circuit including a circuit element provided to read a signal output by the pixel,
wherein, in a region of the other substrate, at least a part of the reading circuit is disposed within an overlapping region overlapping the pixel region in a vertical direction, and
wherein n is an integer greater than or equal to 2 and m is an integer greater than or equal to 1 and less than or equal to n.
